(19) United States
(12) Patent Application Publication
(10) Pub. No.: US 2026/0362881 A1
(43) Pub. Date: Nov. 12, 2026

(54) DISPLAY DEVICE HAVING SEMICONDUCTOR LIGHT-EMITTING ELEMENT, AND APPARATUS FOR MANUFACTURING SAME

(71) Applicant: LG ELECTRONICS INC., Seoul (KR)

(72) Inventors: Hyunwoo CHO, Seoul (KR); Bongchu SHIM, Seoul (KR); Jinhyung JUN, Seoul (KR); Kitae AN, Seoul (KR)

(73) Assignee: LG ELECTRONICS INC., Seoul (KR)

(21) Appl. No.: 19/134,543

(22) PCT Filed: Dec. 2, 2022
(86) PCT No.: PCT/KR2022/019536

§ 371 Date: May 30, 2025

(51) Int. Cl. H10H 29/49; H10H 29/01; H10H 29/854

(52) U.S. Cl. CPC H10H 29/49; H10H 29/012; H10H 29/0362; H10H 29/854

(57) ABSTRACT

The embodiment relates to a display device of a semiconductor light-emitting element and a manufacturing device thereof. The display device of a semiconductor light-emitting element according to the embodiment may include a substrate of a first display module and a substrate of a second display module that are arranged adjacently, a plurality of semiconductor light-emitting element assemblies arranged on the substrates of the first and second display modules, first and second side wirings that are arranged on the sides of the substrates of the first and second display modules and are electrically connected to the semiconductor light-emitting element assemblies, a lower sealing layer arranged on the lower side between the substrate of the first display module and the substrate of the second display module, and a resin layer arranged on the lower sealing layer between the substrate of the first display module and the substrate of the second display module.

### TECHNICAL FIELD

The present invention relates to a display device including a semiconductor light emitting device and a manufacturing device thereof.

### BACKGROUND ART

Large-area display devices include liquid crystal displays (LCDs), OLED displays, and micro-LED displays.

Micro-LED displays are displays that use micro-LEDs, semiconductor light emitting devices with a diameter or cross-sectional area of 100 μm or less, as display devices.

Micro-LED displays have excellent performance in many characteristics such as contrast ratio, response speed, color reproducibility, viewing angle, brightness, resolution, lifespan, luminous efficiency, and brightness because they use micro-LEDs, semiconductor light emitting devices, as display devices.

In particular, micro-LED displays have the advantage of being able to freely adjust the size and resolution by separating and combining the screen in a modular manner, and the advantage of being able to implement a flexible display.

However, since large micro-LED displays require millions or more micro-LEDs, there is a technical problem that makes it difficult to quickly and accurately transfer micro-LEDs to the display panel.

Recently developed transfer technologies include the pick and place process, the laser lift-off method, and the self-assembly method. Among these, the self-assembly method is a method in which semiconductor light emitting devices find their own assembly positions in a fluid, which is advantageous for implementing large-screen display devices.

Meanwhile, conventional display devices using semiconductor light emitting devices are manufactured by transferring semiconductor light emitting devices onto substrates such as TFT substrates or wiring substrates, but productivity is low due to the transfer defect rate of semiconductor light emitting devices, and in particular, there is a problem in that the production yield of large-area display devices is extremely low.

To solve these problems, research and development are currently being conducted on ‘multi-screen display devices’ that implement large display devices by tiling a plurality of semiconductor light emitting diode display modules with relatively small sizes.

However, in the case of multi-screen display devices, a gap area may occur between the connected unit display devices due to the bezel area existing at the edge of each unit display device. The bezel area exists due to side electrodes (or side wiring) for electrical connection between the components disposed on the upper side of the substrate and the components disposed on the lower side of the substrate.

When one image is displayed on the entire area of the multi-screen display device, this gap area may be recognized as a ‘visually recognized’ seam between the modules, which may cause a sense of disconnection and heterogeneity in the image, thereby reducing the immersion of the image.

Meanwhile, there are studies to improve the seam between modules in multi-screen display devices in which the plurality of display modules are tiled in the prior art.

For example, prior art 1 (Korean publication number: 10-2019-0046684) has a structure in which a light absorbing layer is disposed on each mold side, but there is still a gap in the light absorbing layer between adjacent display modules, so there is a limitation in that a seam exists.

In addition, prior art 2 (Korean publication number: 10-2020-0014057) has a structure in which a PR film is placed on the seam area between modules, but if there is still empty space between the modules and the PR film is poorly attached, a visibility problem may occur due to the seam area. In addition, since the seam area is an empty space, it is difficult to attach a PR film thereon, and if PR is attached to the pixel, pixel defects may occur.

Meanwhile, in prior art, the plurality of display modules are tiled on a certain chassis or cabinet, but separate physical bonding between the side areas of adjacent display modules is not attempted, so there is a problem of weak mechanical reliability.

Meanwhile, in the display device of the internal technology, even if the gap between the tiled display modules is physically and mechanically reduced or eliminated, there is a problem in that the boundary line is optically and visually recognized as a seam.

Accordingly, it is necessary to not only physically eliminate the gap between display modules, but also to optically prevent it from being recognized as a seam.

In addition, in the internal technology, in a multi-screen display device where the plurality of display modules are tiled, a height difference occurs between the upper surfaces of the tiled display modules, resulting in a surface step between the display modules.

Accordingly, even if the gap between the display modules is filled, if a surface step occurs between the display modules, there is a problem in that it is optically recognized as a serious seam.

### DISCLOSURE

### Technical Problem

One of the technical objects of the embodiment is to solve the problem of weak mechanical reliability between the side areas of adjacent display modules when the plurality of display modules are tiled.

Another technical object of the embodiment is to solve the problem of not physically eliminating the gap between the display modules but optically and visually not recognizing it as a seam.

Another technical object of the embodiment is to solve the problem of optically recognizing it as a serious seam when a surface step occurs between the display-modules even if the gap between the display modules is filled.

Also, one of the technical objects of the embodiment is to solve the problem of seam phenomenon caused by void (V) occurrence when filling the gap between display modules.

The technical objects of the embodiment are not limited to those described in this item, but include those that may be identified throughout the entire specification.

### Technical Solution

A display device of a semiconductor light emitting device according to an embodiment may include a substrate of a first display module and a substrate of a second display module that are disposed adjacently, a plurality of semiconductor light emitting device assemblies disposed on the substrates of the first and second display modules, first and second side wirings disposed on sides of the substrates of the first and second display modules and electrically connected to the semiconductor light emitting device assemblies, a lower sealing layer disposed on a lower side between the substrate of the first display module and the substrate of the second display module, and a resin layer disposed on the lower sealing layer between the substrate of the first display module and the substrate of the second display module.

The resin layer may include a resin layer having an inclined upper surface, which is disposed in a boundary area between the first display module and the second display module.

The upper surface of the inclined resin layer may be flat.

The upper surface of the inclined resin layer may be parallel to a connecting line between the first flattening layer on the first display module and the second flattening layer on the second display module.

The resin layer may include a porous adhesive resin layer.

The resin layer may include a viscoelastic resin layer.

In addition, a manufacturing device for a display device of a semiconductor light emitting device may include a display device including a plurality of display modules, an upper sealing layer disposed on the plurality of display modules, a lower sealing layer disposed under the plurality of display modules, and a device for injecting a resin material into a space formed by the upper sealing layer and the lower sealing layer.

The device for injecting a resin material includes a plurality of injection devices, and at least one of the plurality of injection devices may include an injection and pressurization device for the resin material.

At least one of the plurality of injection devices may include a suction device for the resin material.

### Advantageous Effects

The display device of the semiconductor light emitting device according to the embodiment has a technical effect that may solve the problem of weak mechanical reliability between the side areas of adjacent display modules when a plurality of display modules are tiled.

For example, according to the embodiment, there is a technical effect that a perfect seamless implementation is possible because the modules are directly bonded using a resin layer of a porous adhesive material as a medium, and thus there is no gap between the modules themselves. In addition, according to the embodiment, there is a technical effect that the modules are directly bonded using a resin layer of a porous adhesive material as a medium, and thus there is no need to separately fix the modules, and there is excellent structural reliability.

In addition, the display device of the semiconductor light emitting device according to the embodiment has a technical effect of not only physically eliminating the gap between the display modules, but also not recognizing it as a seam optically and visually.

For example, in the embodiment, the upper sealing layer 810 and the lower sealing layer 820 are disposed on the space between the adjacent first to fourth display modules 700a, 700b, 700c, 700d and are closely bonded to the flattening film 750 and the wiring protection layer 742, respectively, to form a sealing space, thereby having a special technical effect of allowing the resin layer to fill the space evenly and quickly without overflowing it and leaving any empty space.

For example, the resin layer of the porous adhesive material of the embodiment functions as a light-absorbing layer as a soft porous material, and has a special technical effect of reducing the reflection of external light into the porous space and trapping it, thereby reducing the recognition of the depth.

Specifically, the embodiment has a special technical effect of not recognizing the boundary line as the porous adhesive material or the resin layer is placed between the adjacent first display module 700a and second display module 700b, and thus not recognizing the depth optically or visually.

In addition, the display device of the semiconductor light emitting device according to the embodiment has a technical effect that may solve the problem of being optically recognized as a serious seam when a surface step occurs between the display modules even if the gap between the display modules is filled.

For example, the embodiment has a special technical effect that, even if there is a height difference between the upper surface 700aT of the tiled first display module and the upper surface 700bT of the second display module, the resin layer of the porous adhesive material is disposed so that it functions as a seam light-absorbing layer and diffusely reflects and traps the reflection by external light into the porous space so that it is not optically and visually recognized as a seam.

In addition, the display device according to the embodiment may arrange a resin layer of a viscoelastic material on the first display module 700a and the second display module 700b, and this resin layer of a viscoelastic material may reduce reflection due to external light, thereby reducing seam recognition.

In addition, according to the embodiment, there is a special technical effect that may solve the problem of optically recognizing a seam even if a surface difference occurs between the display modules while filling the gap between the display modules.

For example, according to the third embodiment, even if there is a height difference between the upper surface 700aT of the tiled first display module and the upper surface 700bT of the second display module, since the inclined second resin layer 792 is disposed, the step (E-SS) in the embodiment is covered by the inclined second resin layer 792, thereby solving the problem of optically recognizing a seam.

The technical effects of the embodiments are not limited to those described in this article, but include those that may be understood throughout the entire specification.

### DESCRIPTION OF DRAWINGS

FIG. 1 is an exemplary diagram of a living room of a house in which a display device according to an embodiment is disposed.

FIG. 2 is a block diagram schematically showing a display device according to an embodiment.

FIG. 3 is a circuit diagram showing an example of a pixel of FIG. 2.

FIG. 4 is an enlarged view of a first panel area in the display device of FIG. 1.

FIG. 5 is a cross-sectional view along the line B1-B2 of area A2 of FIG. 4.

FIG. 6 is an exemplary diagram of a light emitting device according to an embodiment being assembled to a substrate by a self-assembly method.

FIG. 7 is an exemplary diagram of a multi-screen display device including a plurality of display panels according to an internal technology.

FIG. 8 is an exemplary diagram of a surface photograph of a first area of a display device including a plurality of display panels illustrated in FIG. 7.

FIG. 9A is an exemplary diagram of a surface photograph of a second area (C2) of a display device 700 including a plurality of display panels illustrated in FIG. 7.

FIG. 9B is a 3D profile data for each component of FIG. 9A.

FIG. 9C is a product photograph in the case where a predetermined resin is applied to the boundary area of the first display module 600a and the second display module 600b in the internal technology using a rear peeling method.

FIG. 10 is a side view of the boundary area between the display modules of the display device 700 according to the first embodiment.

FIG. 11 is a side view of the boundary area between the display modules of the display device 702 according to the second embodiment.

FIG. 12A is an example diagram of a manufacturing method of the display device 700 according to the first embodiment.

FIG. 12B is another example diagram of a manufacturing method of the display device 700 according to the first embodiment.

FIG. 13 is an example diagram of a manufacturing device 800 of the display device according to the embodiment.

FIG. 14A is an example diagram of a multi-screen display device 700 including a plurality of display panels according to an embodiment.

FIG. 14B is an example diagram of a surface photograph of a third area (C3) of the display device 700 illustrated in FIG. 14A.

FIG. 14C is an example diagram of a surface photograph of a fourth area (C4) of the display device 700 illustrated in FIG. 14A.

FIG. 15A is a side view of a boundary area between display modules of a display device 703 according to a third embodiment.

FIG. 15B is a 3D profile data for each component of FIG. 15A.

### MODE FOR INVENTION

Hereinafter, the embodiments disclosed in this specification will be described in detail with reference to the attached drawings. The suffixes ‘module’ and ‘part’ used in the following description for components are given or used interchangeably in consideration of the ease of writing the specification, and do not have distinct meanings or roles in themselves. In addition, the attached drawings are intended to facilitate easy understanding of the embodiments disclosed in this specification, and the technical ideas disclosed in this specification are not limited by the attached drawings. In addition, when an element such as a layer, region, or substrate is mentioned as existing ‘on’ another element, this includes that it may be directly on the other element, or that other intermediate elements may exist between them.

The display devices described in this specification may include digital TVs, mobile phones, smart phones, laptop computers, digital broadcasting terminals, personal digital assistants (PDAs), portable multimedia players (PMPs), navigation devices, slate PCs, tablet PCs, Ultra-Books, desktop computers, and the like. However, the configuration according to the embodiments described in this specification may also be applied to devices capable of displaying, even if they are new product types developed in the future.

The following describes a light emitting device according to an embodiment and a display device including the same.

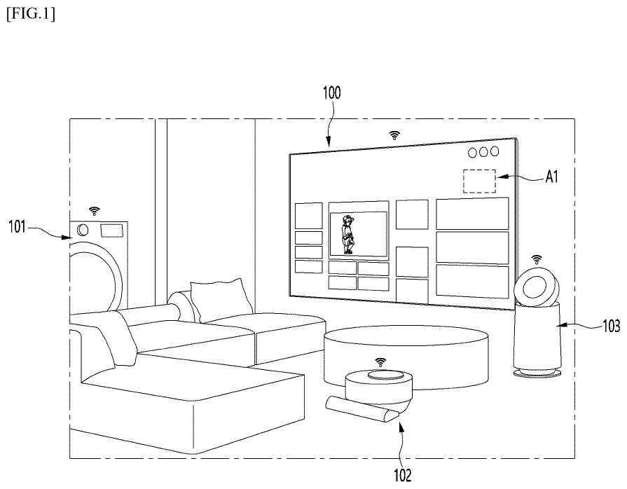

FIG. 1 illustrates a living room of a house in which a display device 100 according to an embodiment is placed.

The display device 100 according to the embodiment may display the status of various electronic products such as a washing machine 101, a robot vacuum cleaner 102, and an air purifier 103, and may communicate with each electronic product based on IOT and control each electronic product based on user setting data.

The display device 100 according to the embodiment may include a flexible display manufactured on a thin and flexible substrate. The flexible display may be bent or rolled like paper while maintaining the characteristics of a conventional flat panel display.

In a flexible display, visual information may be implemented by independently controlling the light emission of unit pixels disposed in a matrix form. A unit pixel means a minimum unit for implementing one color. A unit pixel of a flexible display may be implemented by a light emitting device. In an embodiment, the light emitting device may be a Micro-LED or a Nano-LED, but is not limited thereto.

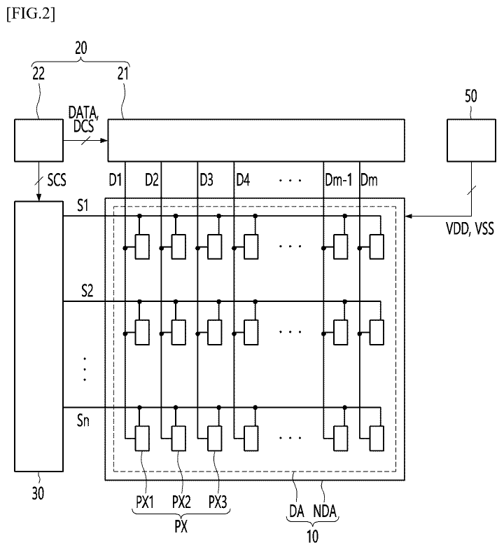

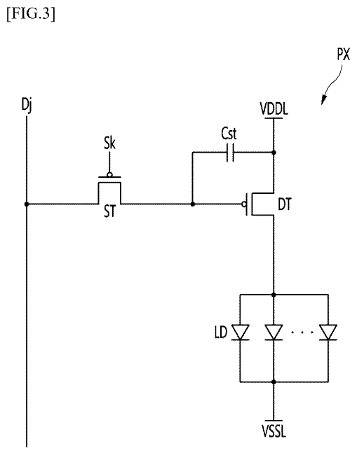

FIG. 2 is a block diagram schematically showing a display device according to an embodiment, and FIG. 3 is a circuit diagram showing an example of a pixel of FIG. 2.

Referring to FIGS. 2 and 3, a display device according to an embodiment may include a display panel 10, a driving circuit 20, a scan driving unit 30, and a power supply circuit 50.

The display device 100 of the embodiment may drive the light emitting device in an active matrix (AM) method or a passive matrix (PM) method.

The driving circuit 20 may include a data driving unit 21 and a timing control unit 22.

The display panel 10 may be divided into a display area (DA) and a non-display area (NDA) disposed around the display area (DA). The display area (DA) is an area where pixels (PX) are formed to display an image. The display panel 10 may include data lines (D1 to Dm), m is an integer greater than or equal to 2, scan lines (S1) to Sn, n is an integer greater than or equal to 2 intersecting the data lines (D1 to Dm), a high-potential voltage line to which a high-potential voltage is supplied, a low-potential voltage line to which a low-potential voltage is supplied, and pixels (PX) connected to the data lines (D1 to Dm) and the scan lines (S1) to Sn).

Each of the pixels (PX) may include a first sub-pixel (PX1), a second sub-pixel (PX2), and a third sub-pixel (PX3). The first sub-pixel (PX1) may emit a first color light of a first wavelength, the second sub-pixel (PX2) may emit a second color light of a second wavelength, and the third sub-pixel (PX3) may emit a third color light of a third wavelength. The first color light may be red light, the second color light may be green light, and the third color light may be blue light, but is not limited thereto. In addition, although FIG. 2 illustrates that each of the pixels (PX) includes three sub-pixels, it is not limited thereto. That is, each of the pixels (PX) may include four or more sub-pixels.

Each of the first sub-pixel (PX1), the second sub-pixel (PX2), and the third sub-pixel (PX3) may be connected to at least one of the data lines (D1 to Dm), at least one of the scan lines (S1 to Sn), and a high-potential voltage line. The first sub-pixel (PX1) may include light emitting devices (LD), a plurality of transistors for supplying current to the light emitting devices (LD), and at least one capacitor (Cst), as shown in FIG. 3.

Although not shown in the drawing, each of the first sub-pixel (PX1), the second sub-pixel (PX2), and the third sub-pixel (PX3) may include only one light emitting device (LD) and at least one capacitor (Cst).

Each of the light emitting devices (LD) may be a semiconductor light emitting diode including a first electrode, a plurality of conductivity-type semiconductor layers, and a second electrode. Here, the first electrode may be an anode electrode, and the second electrode may be a cathode electrode, but is not limited thereto.

Referring to FIG. 3, the plurality of transistors may include a driving transistor (DT) that supplies current to the light emitting devices (LD), and a scan transistor (ST) that supplies a data voltage to a gate electrode of the driving transistor (DT). The driving transistor (DT) may include a gate electrode connected to a source electrode of the scan transistor (ST), a source electrode connected to a high-potential voltage line to which a high-potential voltage is applied, and a drain electrode connected to first electrodes of the light emitting devices (LD). The scan transistor (ST) may include a gate electrode connected to a scan line (Sk, where k is an integer satisfying 1≤k≤n), a source electrode connected to the gate electrode of the driving transistor (DT), and a drain electrode connected to a data line (Dj, where j is an integer satisfying 1≤j≤m).

The capacitor (Cst) is formed between the gate electrode and the source electrode of the driving transistor (DT). The storage capacitor (Cst) may charge the difference between the gate voltage and the source voltage of the driving transistor (DT).

The driving transistor (DT) and the scan transistor (ST) may be formed as thin film transistors. In addition, in FIG. 3, the driving transistor (DT) and the scan transistor (ST) are described as being formed as P-type MOSFETs (Metal Oxide Semiconductor Field Effect Transistors), but the embodiment is not limited thereto. The driving transistor (DT) and the scan transistor (ST) may also be formed as N-type MOSFETs. In this case, the positions of the source electrodes and the drain electrodes of each of the driving transistor (DT) and the scan transistor (ST) may be changed.

In addition, although FIG. 3 illustrates that each of the first sub-pixel (PX1), the second sub-pixel (PX2), and the third sub-pixel (PX3) includes a 2T1C 2 Transistor-1 capacitor) having one driving transistor (DT), one scan transistor (ST), and one capacitor (Cst), the embodiment is not limited thereto. Each of the first sub-pixel (PX1), the second sub-pixel (PX2), and the third sub-pixel (PX3) may include a plurality of scan transistors (ST) and a plurality of capacitors (Cst).

Referring again to FIG. 2, the driving circuit 20 outputs signals and voltages for driving the display panel 10. For this purpose, the driving circuit 20 may include a data driving unit 21 and a timing control unit 22.

The data driving unit 21 receives digital video data (DATA) and a source control signal (DCS) from the timing control unit 22. The data driving unit 21 converts digital video data (DATA) into analog data voltages according to the source control signal (DCS) and supplies the same to the data lines (D1 to Dm) of the display panel 10.

The timing control unit 22 receives digital video data (DATA) and timing signals from the host system. The timing signals may include a vertical sync signal, a horizontal sync signal, a data enable signal, and a dot clock. The host system may be an application processor of a smartphone or tablet PC, a monitor, a system on chip of a TV, etc.

The scan driving unit 30 receives a scan control signal (SCS) from the timing control unit 22. The scan driving unit 30 generates scan signals according to the scan control signal (SCS) and supplies them to the scan lines (S1 to Sn) of the display panel 10. The scan driving unit 30 may include a plurality of transistors and may be formed in a non-display area (NDA) of the display panel 10. Alternatively, the scan driver 30 may be formed as an integrated circuit, in which case it may be mounted on a gate flexible film attached to the other side of the display panel 10.

The power supply circuit 50 may generate a high-potential voltage (VDD) and a low-potential voltage (VSS) for driving the light emitting devices (LD) of the display panel 10 from the main power supply and supply them to the high-potential voltage line and the low-potential voltage line of the display panel 10. In addition, the power supply circuit 50 may generate and supply driving voltages for driving the driving circuit 20 and the scan driving unit 30 from the main power supply.

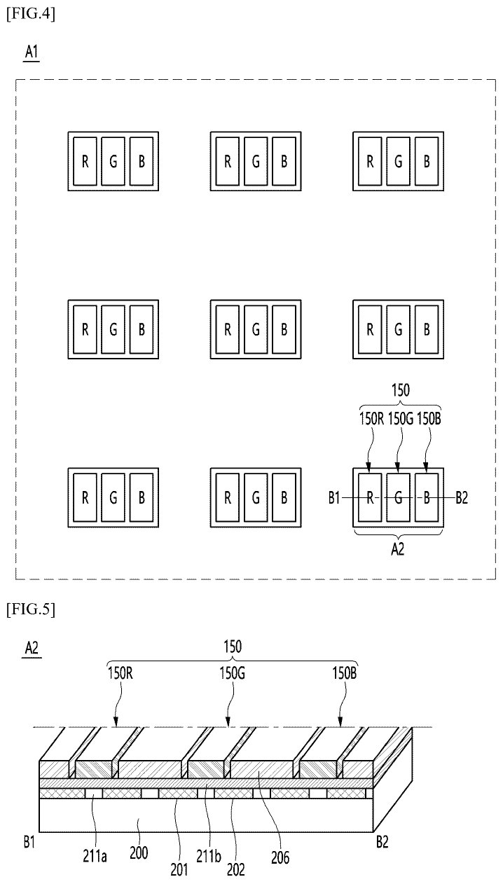

FIG. 4 is an enlarged view of the first panel area (A1) in the display device of FIG. 1.

According to FIG. 4, the display device 100 of the embodiment may be manufactured by mechanically and electrically connecting a plurality of panel areas such as the first panel area (A1) by tiling.

The first panel area (A1) may include a plurality of light emitting devices 150 disposed for each unit pixel (PX of FIG. 2).

For example, the unit pixel (PX) may include a first sub-pixel (PX1), a second sub-pixel (PX2), and a third sub-pixel (PX3). For example, a plurality of red light emitting devices 150R may be disposed in the first sub-pixel (PX1), a plurality of green light emitting devices 150G may be disposed in the second sub-pixel (PX2), and a plurality of blue light emitting devices 150B may be disposed in the third sub-pixel (PX3). The unit pixel (PX) may further include a fourth sub-pixel in which no light emitting devices are disposed, but this is not limited thereto. Meanwhile, the light emitting device 150 may be a semiconductor light emitting device.

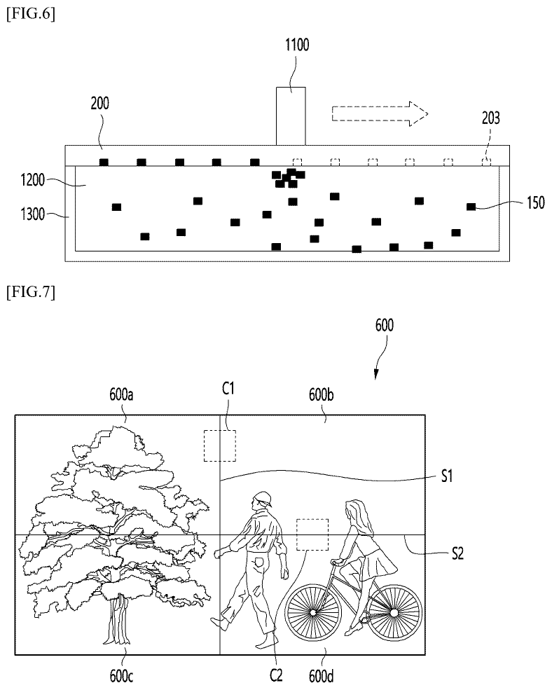

Next, FIG. 5 is a cross-sectional view along the line B1-B2 of the A2 region of FIG. 4.

Referring to FIG. 5, the display device 100 of the embodiment may include a substrate 200, an assembly wiring 201, 202, a first insulating layer 211a, a second insulating layer 211b, a third insulating layer 206, and a plurality of light emitting devices 150.

The assembly wiring may include a first assembly wiring 201 and a second assembly wiring 202 that are spaced apart from each other. The first assembly wiring 201 and the second assembly wiring 202 may be provided to generate a dielectric force for assembling the light emitting device 150. In addition, the first assembly wiring 201 13 and the second assembly wiring 202 may be electrically connected to the electrode of the light emitting device to function as an electrode of the display panel.

The assembly wiring 201, 202 may be formed of a light-transmitting electrode (ITO) or may include a metal material having excellent electrical conductivity. For example, the assembly wiring 201, 202 may be formed of at least one of titanium (Ti), chromium (Cr), nickel (Ni), aluminum (Al), platinum (Pt), gold (Au), tungsten (W), and molybdenum (Mo), or an alloy thereof.

A first insulating layer 211a may be disposed between the first assembly wiring 201 and the second assembly wiring 202, and a second insulating layer 211b may be disposed on the first assembly wiring 201 and the second assembly wiring 202. The first insulating layer 211a and the second insulating layer 211b may be an oxide film, a nitride film, or the like, but are not limited thereto.

The light emitting device 150 may include a red light emitting device 150, a green light emitting device 150G, and a blue light emitting device 150B to form a unit pixel (sub-pixel), but is not limited thereto, and may include a red fluorescent element and a green fluorescent element to implement red and green, respectively.

The substrate 200 may be formed of glass or polyimide. In addition, the substrate 200 may include a flexible material such as PEN (Polyethylene Naphthalate) or PET (Polyethylene Terephthalate). In addition, the substrate 200 may be a light-transmitting material, but is not limited thereto.

The third insulating layer 206 may include an insulating and flexible material such as polyimide, PEN, PET, etc., and may be formed integrally with the substrate 200 to form a single substrate.

The third insulating layer 206 may be a conductive adhesive layer having adhesiveness and conductivity, and the conductive adhesive layer may be flexible to enable a flexible function of the display device. For example, the third insulating layer 206 may be a conductive adhesive layer such as an anisotropic conductive film (ACF) or an anisotropic conductive medium, a solution containing conductive particles, etc. The conductive adhesive layer may be a layer that is electrically conductive in a vertical direction relative to the thickness, but electrically insulating in a horizontal direction relative to the thickness.

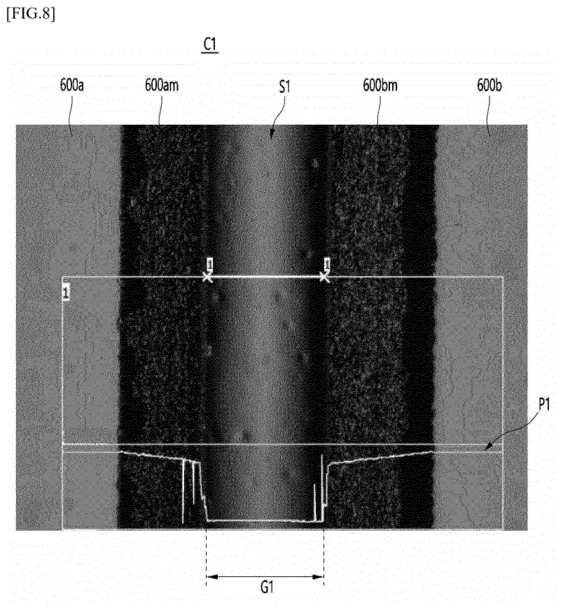

The third insulating layer 206 may include an assembly hole 203 into which a light emitting device 150 is inserted (see FIG. 6). Therefore, during self-assembly, the light emitting device 150 may be easily inserted into the assembly hole 203 of the third insulating layer 206. The assembly hole 203 may be called an insertion hole, a fixing hole, an alignment hole, etc.

The gap between the assembly wiring 201, 202 is formed smaller than the width of the light emitting device 150 and the width of the assembly hole 203, so that the assembly position of the light emitting device 150 may be fixed more precisely using an electric field.

A third insulating layer 206 is formed on the assembly wiring 201, 202 to protect the assembly wiring 201, 202 from the fluid 1200 and prevent leakage of current flowing in the assembly wiring 201, 202. The third insulating layer 206 may be formed as a single layer or a plurality of layers of an inorganic insulator such as silica or alumina or an organic insulator.

In addition, the third insulating layer 206 may include an insulating and flexible material such as polyimide, PEN, PET, etc., and may be formed integrally with the substrate 200 to form a single substrate.

The third insulating layer 206 may be an adhesive insulating layer or a conductive adhesive layer having conductivity. The third insulating layer 206 may be flexible and may enable a flexible function of the display device.

The third insulating layer 206 may have a partition wall, and an assembly hole 203 may be formed by the partition wall. For example, when forming the substrate 200, a part of the third insulating layer 206 may be removed, so that each of the light emitting devices 150 may be assembled into the assembly hole 203 of the third insulating layer 206.

An assembly hole 203 in which the light emitting devices 150 are combined is formed in the substrate 200, and a surface on which the assembly hole 203 is formed may be in contact with a fluid 1200. The assembly hole 203 may guide the exact assembly position of the light emitting device 150.

Meanwhile, the assembly hole 203 may have a shape and size corresponding to the shape of the light emitting device 150 to be assembled at the corresponding position. Accordingly, it is possible to prevent another light emitting device from being assembled in the assembly hole 203 or a plurality of light emitting devices from being assembled.

FIG. 6 is a drawing showing an example of a light emitting device according to an embodiment being assembled on a substrate by a self-assembly method, and the self-assembly method of the light emitting device is explained with reference to the drawings.

The substrate 200 may be a panel substrate of a display device. In the following description, the substrate 200 is described as a panel substrate of a display device, but the embodiment is not limited thereto.

Referring to FIG. 6, a plurality of light emitting devices 150 may be introduced into a chamber 1300 filled with a fluid 1200. The fluid 1200 may be water such as ultrapure water, but is not limited thereto. The chamber may be called a tank, a container, a vessel, etc.

After this, the substrate 200 may be placed on the chamber 1300. According to an embodiment, the substrate 200 may be introduced into the chamber 1300.

As shown in FIG. 5, a pair of assembly wirings 201, 202 corresponding to each light emitting device 150 to be assembled may be placed on the substrate 200.

Referring to FIG. 6, after the substrate 200 is placed, an assembly device 1100 including a magnetic body may move along the substrate 200. For example, a magnet or an electromagnet may be used as the magnetic body. The assembly device 1100 may move in contact with the substrate 200 to maximize the area to which the magnetic field is applied into the fluid 1200. In some embodiments, the assembly device 1100 may include a plurality of magnetic bodies or may include magnetic bodies of a size corresponding to the substrate 200. In this case, the movement distance of the assembly device 1100 may be limited within a predetermined range.

The light emitting device 150 in the chamber 1300 may move toward the assembly device 1100 by the magnetic field generated by the assembly device 1100.

While the light emitting device 150 is moving toward the assembly device 1100, it may enter the assembly hole 203 by the dielectrophoretic force (DEP force) and come into contact with the substrate 200.

Specifically, the assembly wiring 201, 202 forms an electric field by the power supplied from the outside, and the dielectrophoretic force may be formed between the assembly wiring 201, 202 by this electric field. The light emitting device 150 may be fixed to the assembly hole 203 on the substrate 200 by this dielectrophoretic force.

The light emitting device 150 in contact with the substrate 200 may be prevented from being detached by the movement of the assembly device 1100 due to the electric field applied by the assembly wiring 201, 202 formed on the substrate 200. According to the embodiment, the time required for each light emitting device 150 to be assembled on the substrate 200 may be drastically shortened by the self-assembly method using the above-described electromagnetic field, so that a large-area, high-pixel display may be implemented more quickly and economically.

At this time, a predetermined solder layer (not shown) is formed between the light emitting device 150 assembled on the assembly hole 203 of the substrate 200 and the assembly electrode, thereby improving the bonding strength of the light emitting device 150.

Next, a molding layer (not shown) may be formed on the assembly hole 203 of the substrate 200. The molding layer may be a light-transmitting resin or a resin containing a reflective material or a scattering material.

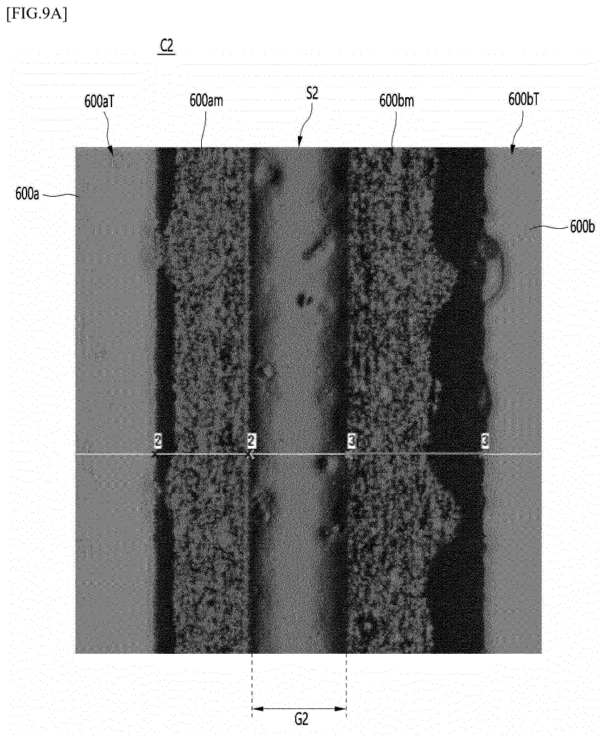

FIG. 7 illustrates a multi-screen display device 600 including a plurality of display panels according to an internal technology.

Referring to FIG. 7, the multi-screen display device 600 may be implemented in a form in which the plurality of display panels 600a to 600d are tiled. For example, the multi-screen display device 600 may include first to fourth display panels 600a, 600b, 600c, 600d, but is not limited thereto. Each of the plurality of display panels 600a to 600d may be a display device manufactured by the self-assembly method described above, but is not limited thereto.

In the internal technology, the multi-screen display device 600 may be used as a large-area display device that provides one image through the plurality of display panels 600a to 600d, and each of the plurality of display panels 600a to 600d may have a bezel area on the side minimized so that the gap area with the adjacent display device may be reduced.

According to the internal technology, as the gap area between display devices is reduced, the dark area caused by the gap area when outputting an image may be minimized, and accordingly, an image with a minimized sense of disconnection may be displayed on the entire screen of the multi-screen display device 600.

Meanwhile, referring to FIG. 7, there is a problem that the gap or boundary line is recognized as a seam (S1) that is ‘visually recognized’ from an optical perspective, even though the gap, which is a physical gap between the plurality of display panels of the internal technology, has been reduced.

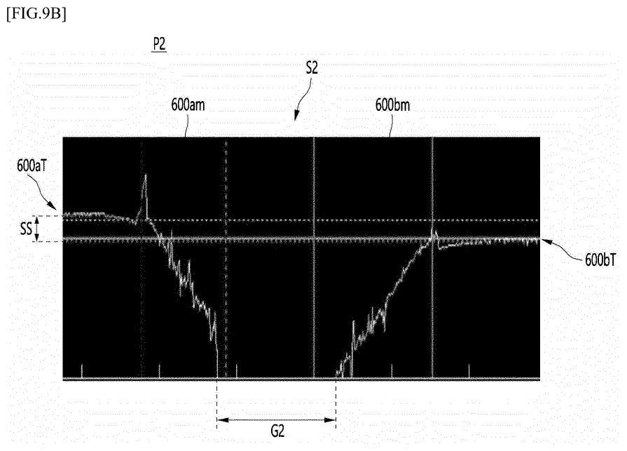

For example, FIG. 8 is an example of a surface photograph of a first area (C1) of a display device 600 including the plurality of display panels illustrated in FIG. 7.

Specifically, FIG. 8 is a surface photograph of a first boundary area (C1) of a first display module 600a and a second display module 600b, and a predetermined gap (G1) exists between a side member 600am of an adjacent first display panel and a side member 600bm of a second display panel. FIG. 8 shows 3D profile data (P1) for each component expressed in the photograph.

In the display device of internal technology, it is difficult to physically and mechanically reduce or eliminate the gap (G1) between tiled display modules using existing technology, and even if the gap is reduced or eliminated, there is a problem that the boundary line is optically and visually recognized as a seam (S1).

Accordingly, it is necessary to prevent the gap (gap) between display modules from being recognized as a seam optically, rather than just physically eliminating it.

In addition, although the plurality of display modules are tiled on a given chassis or cabinet in the internal technology, there is a problem of weak mechanical reliability because there is no separate physical connection between the side areas of adjacent display modules.

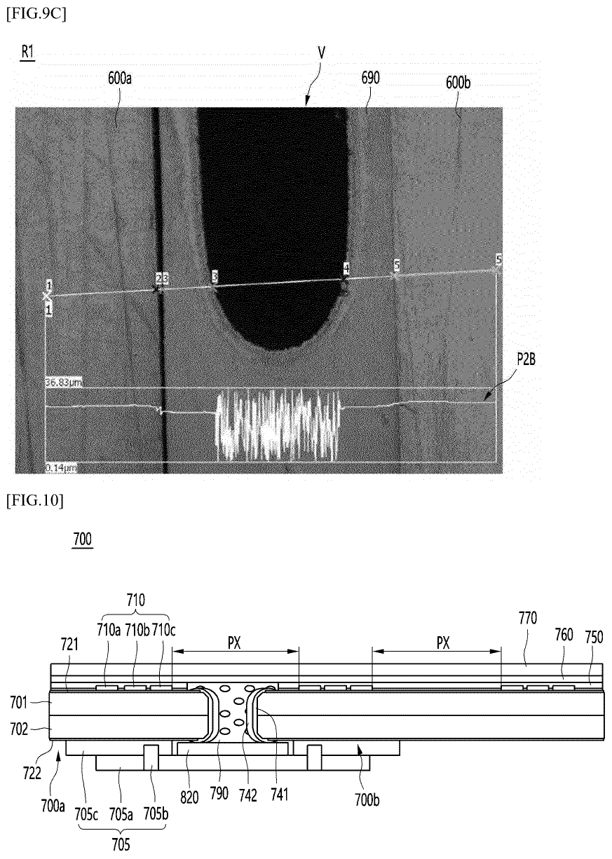

Next, FIG. 9A is an example of a surface photograph of a second area (C2) of a display device 600 including the plurality of display panels as shown in FIG. 7, and FIG. 9B is a 3D profile data (P2) for each component of FIG. 9A.

Specifically, FIG. 9A is a surface photograph of a second boundary area (C2 of a first display module 600a and a second display module 600b, and a predetermined second gap (G2 exists between the side member 600am of the adjacent first display panel and the side member 600bm of the second display panel.

FIG. 9B is a 3D profile data (P2) for each component of FIG. 9A, and a height difference occurs between the upper surface 600aT of the tiled first display panel and the upper surface 600bT of the second display panel, resulting in a surface step (SS) between the display modules.

Next, FIG. 9C is a product photograph (R1 in the case where a predetermined resin is applied to the boundary area of the first display module 600a and the second display module 600b in the internal technology using the back-filling method, and FIG. 9C includes 3D profile data (P2B) for each component of FIG. 9C.

According to the internal technology, even if the gap between the display modules is filled, if a surface step occurs between the display modules, there is a problem that it is recognized as a serious seam (S2) optically and visually, as in FIGS. 9A and 9B.

In addition, according to the internal technology, if the gap between the display modules is filled with a predetermined resin without a sealing cover layer according to the embodiment, not only a surface step occurs between the display modules, but also a void (V) occurs, causing an optical and visual problem of a seam phenomenon.

One of the technical objects of the embodiment is to solve the problem of weak mechanical reliability between the side areas of adjacent display modules when the plurality of display modules are tiled.

Another technical object of the embodiment is to not physically eliminate the gap between the display modules, but to make it not be recognized as a seam optically or visually.

Another technical object of the embodiment is to solve the problem that even if the gap between the display modules is filled, a serious seam is optically recognized when a surface step occurs between the display modules.

Another technical object of the embodiment is to solve the problem of a seam phenomenon occurring due to void (V) occurrence when the gap between the display modules is filled.

Hereinafter, a display device according to an embodiment for solving the above technical problem will be specifically described.

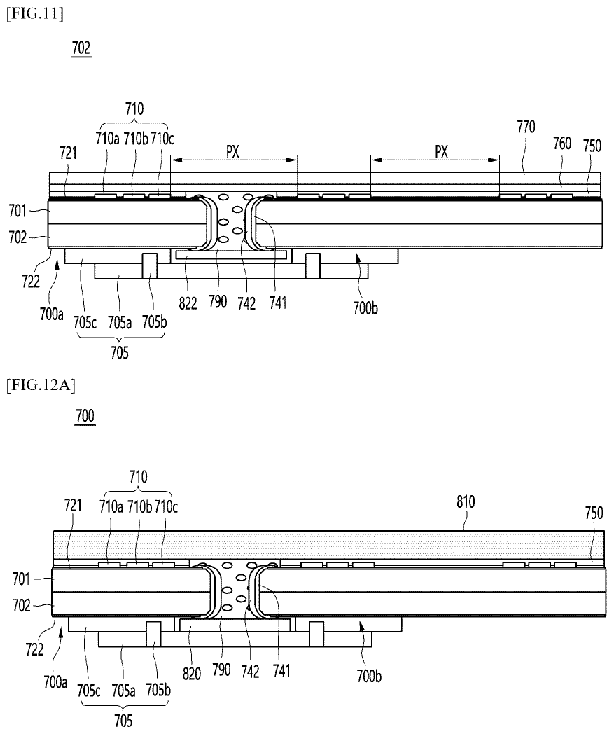

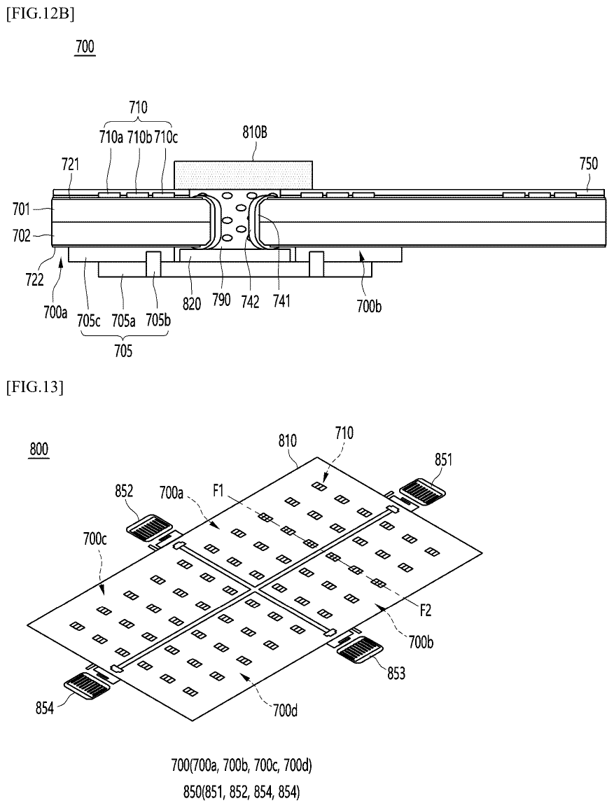

FIG. 10A is a side view of a boundary area between display modules of a display device 700 according to a first embodiment (hereinafter, ‘first embodiment’ will be abbreviated as ‘embodiment’). For example, FIG. 11 is a side view of a boundary area between a first display module 700a and a second display module 700b.

The display device 700 according to the embodiment may be a display device including a plurality of display modules.

For example, the display device 700 may be manufactured by tiling a plurality of display modules, and the display device may be manufactured by tiling in which the semiconductor light emitting device assemblies 710 on adjacent display modules 700a, 700b are disposed in close proximity to each other according to the pitch (PX) and then fixed.

Referring to FIG. 10, the display device 700 according to the embodiment may include at least one of a first module substrate 701, a second module substrate 702, a semiconductor light emitting device assembly 710, a side wiring 741, a wiring protection layer 742, a resin layer 790, a flattening film 750, a black matrix 720, an optical adhesive layer 760, a cover film 770, and a lower sealing layer 820.

For example, a display device 700 according to an embodiment may include a first module substrate 701 and a second module substrate 702 disposed below the first module substrate 701.

The first module substrate 701 may be a TFT substrate on which a TFT (thin film transistor) and wiring are formed, and the second module substrate 702 may be a PCB on which circuits such as a timing controller, a memory, a voltage source for driving a semiconductor light emitting device assembly 710, and various wiring are formed.

In addition, the second module substrate 702 may be a PCB on which a driving unit for applying signals to the gate wiring and data wiring of the first module substrate 701 is formed, respectively. In this case, a plurality of wiring electrodes 721, 722 may be formed on the first module substrate 701 and the second module substrate 702.

In addition, according to an embodiment, a TFT, wiring, and various circuits may be formed on the second module substrate 702, and the first module substrate 701 may be implemented as a protective substrate for protecting the TFT and wiring.

In addition, the display device 700 according to the embodiment may include only one substrate, for example, the first module substrate 701. In this case, the features related to the lower surface of the second module substrate 702 described below may be applied equally to the lower surface of the first module substrate 701.

A plurality of semiconductor light emitting device assemblies 710 may be disposed in an array form on the first module substrate 701. For example, a plurality of semiconductor light emitting device assemblies 710 forming a plurality of rows and columns may be disposed on the first module substrate 701.

The semiconductor light emitting device assembly 710 may adopt the technical features of the semiconductor light emitting device 150 described above.

Each of the plurality of semiconductor light emitting device assemblies 710 is disposed spaced apart at a predetermined pitch (PX) and functions as one pixel, and at least one semiconductor light emitting device may be provided in the semiconductor light emitting device assembly 710.

For example, when the pixel includes R (red), G (green), and B (blue) sub-pixels, the semiconductor light emitting device assembly 710 may include a first semiconductor light emitting device 710a that emits red light, a second semiconductor light emitting device 710b that emits green light, and a third semiconductor light emitting device 710c that emits blue light, but is not limited thereto.

For example, the first to third semiconductor light emitting devices 710a, 710b, 710c are all elements that emit one color, for example, blue light, and by arranging fluorescent materials or QDs thereon, various colors may be implemented through color conversion.

The embodiment may include a plurality of semiconductor light emitting device assemblies 710 and a wiring electrode 721 electrically connected thereto on the first module substrate 701.

In addition, a plurality of wiring electrodes (not shown) formed in a vertical direction with respect to the wiring electrode 721 may be further formed on the first module substrate 701. For example, when the first module substrate 701 is a TFT substrate, the wiring electrode 721 may be implemented as a data wiring or a gate wiring, and the wiring electrode formed vertically with the wiring electrode 721 may be implemented as a different wiring from the wiring electrode 721.

According to an embodiment, the wiring electrode 721 may correspond to a common electrode connected to the p electrode or n electrode of each of the plurality of semiconductor light emitting devices 710.

Meanwhile, the wiring electrode 721 formed on the first module substrate 701 may be electrically connected to a voltage source or circuit of the second module substrate 702 to receive a signal related to driving the plurality of semiconductor light emitting device assemblies 710 or receive power.

The display device 700 according to an embodiment may further include a plurality of electrode pads (not shown) formed in an edge area of the upper surface of the first module substrate 701, and a side electrode 741 formed on a side of the display module. The plurality of electrode pads and the side electrode 741 may be formed of a conductive metal (Cu, Ag, etc.).

The side electrode 741 may be formed on the side surfaces of the first module substrate 701 and the second module substrate 702, respectively. One end of the side electrode 741 may be formed to contact the side surface of the electrode pad on the first module substrate 701, and the other end may be connected to the second wiring electrode 722 formed on the lower portion of the second module substrate 702.

In addition, in the display device 700 according to the embodiment, after the formation of the semiconductor light emitting device assembly 710, the second module substrate 702 may be bonded (adhered, etc.) to the lower portion of the first module substrate 701, and a flattening layer 750 may be formed on the first module substrate 701.

The flattening layer 750 may be formed with a predetermined thickness to cover the upper surface of the first module substrate 701 and the semiconductor light emitting device assembly 710. The flattening layer 750 may provide a flat surface on the upper surface of the display device 700 and may fix the position of the semiconductor light emitting device assembly 710.

The flattening layer 750 may correspond to an encapsulation layer that protects the semiconductor light emitting device assembly 710.

The flattening layer 750 may be formed by a process such as molding or hot melt. For example, the flattening layer 750 may be implemented with a light-transmitting or fluorescent material such as an acrylic resin, a polyimide resin, an epoxy resin, or a polyurethane resin.

Next, the embodiment may include an optical adhesive layer 760 on the flattening layer 750. The optical adhesive layer 760 may be a transparent adhesive material such as OCA (Optical Clear Adhesive) or OCR (Optically Clear Resin), but is not limited thereto.

Next, the embodiment may include a film layer 770 on the optical adhesive layer 760. The film layer 770 may include various optical films such as a polarizing film, an AG film, and an AR film to prevent quality deterioration (e.g., deterioration of black contrast) due to external light incident on an electrode present on the upper surface of the first module substrate 701 being irradiated to the outside together with light emitted from semiconductor light emitting devices.

Meanwhile, according to the internal technology, there is a problem that the gap between the display modules is recognized as a seam due to the gap between the display modules, and in particular, the seam is more visible when the display device is switched to a black state.

Also, according to the internal technology, there is a problem that it is difficult to attach an adhesive layer using OCA or a front cover because there is an empty space between the display modules.

Also, according to the internal technology, there is a problem that the seam is more prominent due to the step (empty space) in the seam portion when the front cover is attached, causing the cover to bend.

Accordingly, the display device 700 according to the embodiment may solve the above technical problem by arranging a resin layer 790 on the first display module 700a and the second display module 700b.

The resin layer 790 may be a porous adhesive resin layer. For example, the porous adhesive resin layer of the embodiment may use at least one porous material among urethane foam or PP (Polypropylene), TPU (Thermo Plastic Polyurethane), TPO (Thermo Plastic Olefin), and compressed styrofoam.

In addition, the porous adhesive resin layer of the embodiment may further include urethane resin, terpene resin, etc. as an adhesive material. In addition, the embodiment may further include a thermoplastic resin such as polystyrene, polyethylene, polypropylene, methacrylic, and acrylic, and may be manufactured by mixing a black pigment into the thermoplastic resin.

The resin layer 790 including the porous adhesive resin layer is a soft porous material, and has a technical effect of trapping reflections due to external light into a porous space by applying a light-absorbing layer, thereby reducing the perception of light.

The porous adhesive resin layer may be a foam series in which an air layer is formed as a porous material, and may have a black color for light absorption. In addition, the porous adhesive resin layer may use a foam resin or a resin to which air dispersion is applied.

The porous adhesive resin layer includes a soft resin and has elasticity, so that it may prevent mechanical damage by being compressed and fixed to a predetermined pitch (PX) between the first display module 700a and the second display module 700b, and may firmly maintain the pitch.

The resin layer 790 may be formed to have a thickness of 200 μm or less, preferably 150 μm or less, but is not limited thereto.

The density of the resin layer 790 may be 0.15 to 0.4 g/cm³, but is not limited thereto.

In addition, the embodiment may further include a soft resin capable of absorbing light of the urethane, epoxy, and silicone series.

In addition, the resin layer 790 in the embodiment may include a viscoelastic resin layer.

The viscoelastic resin layer of the embodiment may include a material such as epoxy or rubber.

In addition, the viscoelastic resin layer may further include a urethane resin, a terpene resin, etc. as an adhesive material. In addition, the viscoelastic resin layer of the embodiment may further include a thermoplastic resin such as polystyrene, polyethylene, polypropylene, methacrylic, acrylic, etc., and may be manufactured by mixing a black pigment into the thermoplastic resin.

The viscoelastic resin layer of the embodiment has a technical effect of reducing the recognition of the mind by trapping the reflection due to external light by applying a light-absorbing layer.

Next, the embodiment may include a lower sealing layer 820 at the lower side of the gap between the adjacent first display module 700a and the second display module 700b.

The lower sealing layer 820 may be formed in the gap between the adjacent first display module 700a and the second display module 700b together with the upper sealing layer 810 described in the manufacturing method below, so that the resin layer may be uniformly filled.

The lower sealing layer 820 may be disposed at the lower gap between the first display module 700a and the second display module 700b before the module frame 705 is fastened to the plurality of modules.

Alternatively, the lower sealing layer 820 may be placed in the lower gap between the first display module 700a and the second display module 700b while being mounted on the connecting frame 705a of the module frame 705.

The lower sealing layer 820 may include an adhesive film such as PSA, a single-sided tape, or a hot melt material.

In addition, another embodiment may form a sealing space by omitting the lower sealing layer 820. For example, in another embodiment, a rubber O-ring, etc. may be added when fastening the module frame 705 to form a sealing space.

Next, FIG. 11 is a side view of a boundary area between display modules of a display device 702 according to the second embodiment.

The second embodiment may adopt the technical features of the first embodiment, and the following description will focus on the features of the first embodiment.

In the second embodiment, the second lower sealing layer 822 may be disposed in the lower gap between the first display module 700a and the second display module 700b before the module frame 705 is connected to a plurality of modules, and the second lower sealing layer 822 may be spaced apart from the module frame 705.

For example, the second lower sealing layer 822 may be disposed spaced apart from the connecting frame 705a of the module frame 705.

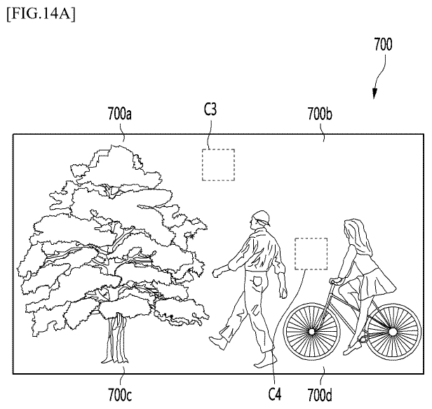

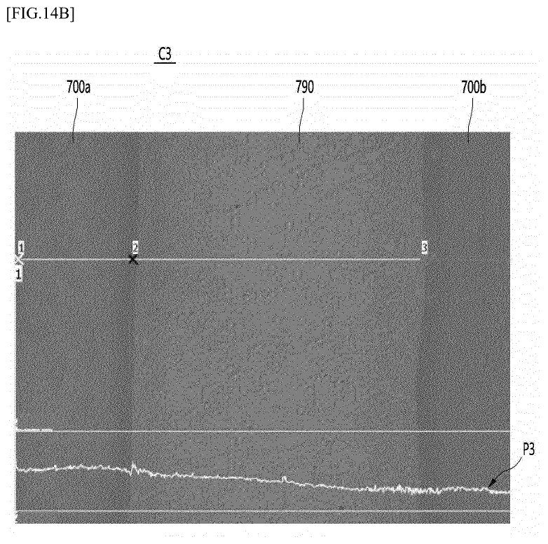

Hereinafter, a method for manufacturing a display device 700 according to an embodiment will be described with reference to FIGS. 12a to 13.

Referring to FIG. 12A, the embodiment may adhere a lower sealing layer 820 to the lower side of the gap between adjacent first display modules 700a and second display modules 700b.

The first display module 700a and the second display module 700b may be in a state where a flattening film 750 is formed.

The lower sealing layer 820 may include an adhesive film such as PSA, a single-sided tape, or a hot melt material.

The lower sealing layer 820 may be formed in a sealing space in the gap between the adjacent first display module 700a and second display module 700b together with the upper sealing layer 810 so that the resin layer 790 may be uniformly filled.

The lower sealing layer 820 may be placed in the lower gap between the first display module 700a and the second display module 700b before the module frame 705 is fastened to a plurality of modules.

Or, the lower sealing layer 820 may be placed in the lower gap between the first display module 700a and the second display module 700b while being mounted on the connecting frame 705a of the module frame 705.

Afterwards, the upper sealing layer 810 may be adhered to the upper side of the gap between the adjacent first display module 700a and the second display module 700b.

For example, the upper sealing layer 810 may be adhered on the flattening film 750 of the adjacent first display module 700a and the second display module 700b.

According to an embodiment, the upper sealing layer 810 may form a sealing space in the gap between the adjacent first display module 700a and second display module 700b together with the lower sealing layer 820, and the sealing space may form a microchannel so that the resin layer 790 may be uniformly filled without being insufficient or overflowing in the sealing space.

The upper sealing layer 810 may include a release protective film, an adhesive polymer such as PDMS or polyurethane, etc.

For example, the upper sealing layer 810 may be closely adhered to the flattening film 750 of the adjacent first display module 700a and second display module 700b to prevent the resin layer 790 from overflowing, and the lower sealing layer 820 may also be closely adhered to the wiring protection layer 742 disposed on the lower side of the adjacent first display module 700a and second display module 700b to form a sealed space, so that the resin layer may fill the space evenly and quickly without overflowing the space and without leaving any empty space.

Next, FIG. 12B is another example of a manufacturing method of a display device 700 according to the first embodiment.

In the manufacturing method described above, the upper sealing layer 810 is completely tightly bonded on the flattening film 750 of the adjacent first display module 700a and second display module 700b.

On the other hand, the other manufacturing method of FIG. 12B is characterized in that the second upper sealing layer 810B is only partially bonded on the gap area between the adjacent first display module 700a and second display module 700b.

According to an embodiment, after the sealing space of the adjacent first display module 700a and second display module 700b is filled with a resin layer 790, the upper sealing layer 810 may be removed, and then an optical adhesive layer 760 and a film layer 770 may be attached on the flattening film 750.

Next, FIG. 13 is an exemplary diagram of a manufacturing device 800 of a display device according to an embodiment.

A manufacturing device 800 of a display device according to an embodiment may include a display device 700 including a plurality of display modules, an upper sealing layer 810 disposed on the plurality of display modules, a lower sealing layer 820 disposed under the plurality of display modules, and a device 850 for injecting a resin material into a space formed by the upper sealing layer 810 and the lower sealing layer 820.

The display device 700 may include a first display module 700a, a second display module 700b, a third display module 700c, and a fourth display module 700d.

The resin material injection device 850 may include a first injection device to a fourth injection device 851, 852, 853, 854.

At least one of the first to fourth injection devices 851, 852, 853, 854 may be a resin material injection device.

In addition, at least one of the first to fourth injection devices 851, 852, 853, 854 may be a suction device.

In addition, at least one of the first to fourth injection devices 851, 852, 853, 854 may be an injection and pressurization device for the resin material. For example, at least one of the first to fourth injection devices 851, 852, 853, 854 may be pressurized while injecting the resin material.

For example, in the first manufacturing device, the first injection device 851 may be a resin material injection and pressurization device. The remaining second to fourth injection devices 852, 853, 854 may be suction devices.

Or, in the second manufacturing device, the first injection device 851 and the second injection device 852 may be resin material injection and pressurization devices. The remaining third injection device 853 and the fourth injection device 854 may be suction devices.

Or, in the third manufacturing device, the first to third injection devices 851, 852, 853 may be resin material injection and pressurization devices. The remaining fourth injection device 854 may be suction devices.

Referring to FIG. 12A and FIG. 13 together, in the embodiment, the upper sealing layer 810 may be formed in a sealing space in the gap between the adjacent first to fourth display modules 700a, 700b, 700c, 700d together with the lower sealing layer 820. FIG. 12A may be a part of a cross-sectional view taken along the line F1-F2 of FIG. 13.

At this time, the resin material may be injected and pressurized through at least one of the first to fourth injection devices 851, 852, 853, 854.

For example, the resin material may be injected and pressurized through the first injection device 851, and may be sucked through the remaining second to fourth injection devices 852, 853, 854.

Or, for example, the resin material may be injected and pressurized through the first to third injection devices 851, 852, 853, and may be sucked through the fourth injection device 854.

For example, the upper sealing layer 810 and the lower sealing layer 820 are disposed in the space between the adjacent first to fourth display modules 700a, 700b, 700c, 700d and are closely bonded to the flattening film 750 and the wiring protection layer 742, respectively, to form a sealing space, thereby providing a special technical effect in that the resin layer may be uniformly and quickly filled without overflowing the space and without leaving a void.

In the internal technology, when filling the resin layer without forming the resin layer through the sealing space using the upper sealing layer 810, there was a problem in that the resin layer was filled to the extent of leaving the gap space or a void space was created.

In addition, since the gaps between the display modules themselves are different in order to maintain the pixel pitch, there was a problem in precisely filling the gaps with a resin layer using a dispensing method or a photo process using exposure.

According to an embodiment, when a resin layer is formed through a sealing space using an upper sealing layer 810, a flat resin layer may be formed evenly in the gaps between modules where the gaps are not constant each time due to the unit module manufacturing tolerance, and since the process time that takes about 2 hours in the photo process in the internal technology may fill the resin layer in about 10 seconds when applying the embodiment, there is a special technical effect that significantly improves the process steps.

In an embodiment, after a resin layer is filled in the sealing space, an exposure process for a predetermined curing may be performed, and then the upper sealing layer 810 may be removed, and then an optical adhesive layer 760 and a film layer 770 may be attached on the flattening film 750.

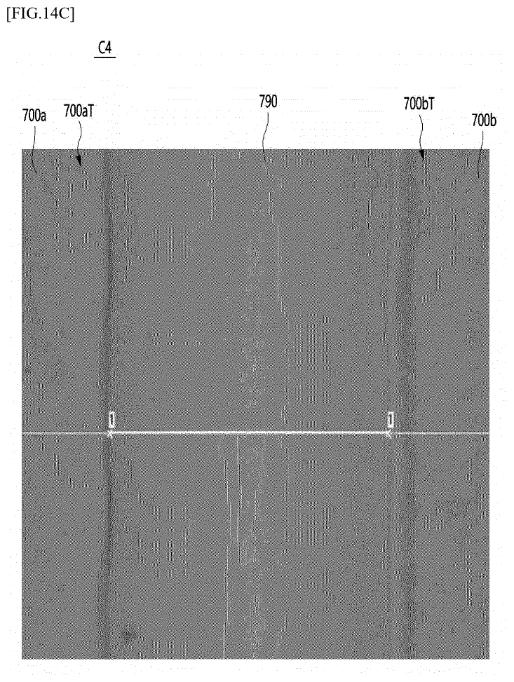

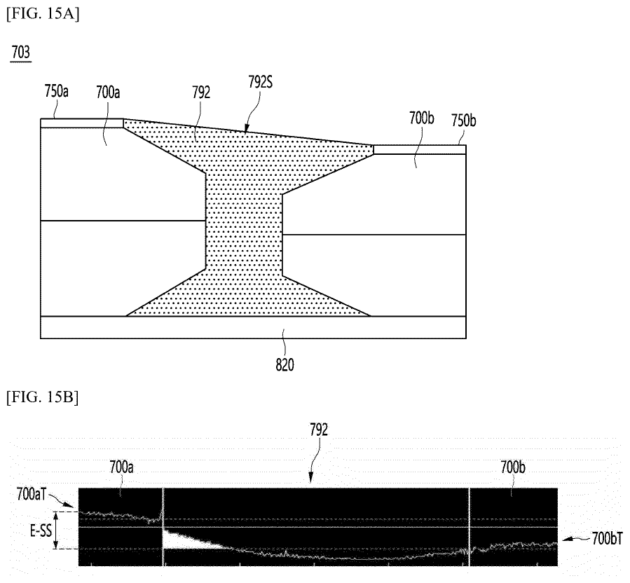

Next, the technical effects of the display device 700 according to the embodiment will be described in detail with reference to FIGS. 14A to 15B.

FIG. 14A illustrates a multi-screen display device 700 including a plurality of display panels according to the embodiment.

FIG. 14B is an example of a surface photograph of the third area (C3) of the display device 700 illustrated in FIG. 14A.

FIG. 14C is an example of a surface photograph of the fourth area (C4) of the display device 700 illustrated in FIG. 14A.

Referring to FIG. 14a, the display device 700 according to the embodiment may be implemented in a form in which a plurality of display panels 700a to 700d are tiled. For example, the multi-screen display device 700 may include, but is not limited to, the first to fourth display panels 700a, 700b, 700c, 700d. Each of the plurality of display panels 700a to 700d may be a display device manufactured by the self-assembly method described above, but is not limited thereto.

Referring to FIG. 14B, unlike the display device 600 of FIG. 7 of the existing internal technology, there is a technical effect in which the boundary area between the plurality of display panels 700a to 700d is not recognized as a depth.

For example, FIG. 14B is an example surface photograph of the third area (C3) of the display device 700 illustrated in FIG. 14A, and 3D profile data (P3 for each component is expressed in the photograph.

Specifically, FIG. 14B is a surface photograph of the third boundary area (C1) of the first display module 700a and the second display module 700b, and since a resin layer 790 is disposed between the adjacent first display modules 700a and second display modules 700b, there is a special technical effect that the boundary line is not recognized optically and visually as a seam.

For example, the resin layer 790 of the embodiment is a soft porous material that functions as a seam absorbing layer, and has a special technical effect that may reduce seam recognition by trapping reflections due to external light into the porous space.

Next, according to the embodiment, there is a technical effect that allows for perfect seamless implementation by directly bonding modules using the resin layer 790 as a medium, so that there is no gap between the modules.

In addition, according to the embodiment, the modules are directly bonded using a resin layer 790 such as a porous adhesive resin layer, so there is no need to separately fix the modules, and there is a technical effect of excellent structural reliability.

Next, FIG. 14C is an example of a surface photograph of the fourth area (C4) of the display device 700 illustrated in FIG. 14A.

Specifically, FIG. 14C is a surface photograph of the fourth boundary area (C4) of the first display module 700a and the second display module 700b, and even if there is a height difference between the upper surface 700aT of the tiled first display module and the upper surface 700bT of the second display module, a resin layer 790 such as a porous adhesive resin layer is disposed, thereby functioning as a deep light-absorbing layer to diffusely reflect and trap the reflection of external light into the porous space, thereby preventing it from being recognized as a seam optically and visually.

Next, FIG. 15A is a side view of a boundary area between display modules of a display device 703 according to the third embodiment, and FIG. 15B is a 3D profile data for each component of FIG. 15A.

The display device 703 according to the third embodiment may adopt the technical features of the first or second embodiment described above, and the following description will focus on the features of the third embodiment.

According to the third embodiment, there is a special technical effect that may solve the problem of optically recognizing a seam even when a surface step occurs between display modules while filling the gap between display modules.

For example, the third embodiment may include an inclined second resin layer 792 disposed at a boundary area between the first display module 700a and the second display module 700b, and the inclined surface 792S of the second resin layer 792 may be substantially parallel to a connection line between the first flattening layer 750a on the first display module 700a and the second flattening layer 750b on the second display module 700b.

In addition, the inclined surface 792S of the second resin layer 792 may be substantially flat.

Also, for example, the inclined surface 792S of the second resin layer 792 may be positioned so as not to cross the connection line between the first flattening layer 750a on the first display module 700a and the second flattening layer 750b on the second display module 700b.

FIG. 15B is a 3D profile data for each component of FIG. 15A, and even if there is a height difference between the upper surface 700aT of the tiled first display module and the upper surface 700bT of the second display module, since the inclined second resin layer 792 is disposed, the step (E-SS) in the embodiment is covered by the inclined second resin layer 792, thereby solving the problem of being optically recognized as a seam, which has a special technical effect.

The above description is merely an exemplary description of the technical idea of the present invention, and those skilled in the art will be able to make various modifications and variations without departing from the essential characteristics of the present invention.

Therefore, the embodiments disclosed in the present invention are not intended to limit the technical idea of the present invention but to explain it, and the scope of the technical idea of the present invention is not limited by these embodiments.

The protection scope of the present invention should be interpreted by the following claims, and all technical ideas within the equivalent scope should be interpreted as being included in the scope of the rights of the present invention.

### INDUSTRIAL APPLICABILITY

The embodiment may be adopted in the field of displays that display images or information.

The embodiment may be adopted in the field of displays that display images or information using semiconductor light emitting devices.

The embodiment may be adopted in the field of displays that display images or information using micro-level or nano-level semiconductor light emitting devices.

1. A display device of a semiconductor light emitting device comprising:
a substrate of a first display module and a substrate of a second display module disposed adjacently;
a plurality of semiconductor light emitting device assemblies disposed on the substrates of the first and second display modules, respectively;
a first side wiring and a second side wiring disposed on the side of the substrates of the first and second display modules, respectively, and electrically connected to the semiconductor light emitting device assembly;
a lower sealing layer disposed on a lower side between the substrate of the first display module and the substrate of the second display module; and
a resin layer disposed on the lower sealing layer between the substrate of the first display module and the substrate of the second display module.

2. The display device of a semiconductor light emitting device according to claim 1, wherein the resin layer comprises an inclined resin layer disposed in a boundary area between the first display module and the second display module and comprising an inclined upper surface.

3. The display device of a semiconductor light emitting device according to claim 2, wherein the upper surface of the inclined resin layer is flat.

4. The display device of a semiconductor light emitting device according to claim 3, wherein the upper surface of the inclined resin layer is parallel to the connection line between a first flattening layer on the first display module and a second flattening layer on the second display module.

5. The display device of a semiconductor light emitting device according to claim 1, wherein the resin layer comprises a porous adhesive resin layer.

6. The display device of a semiconductor light emitting device according to claim 1, wherein the resin layer comprises a viscoelastic resin layer.

7. A manufacturing device for display device of a semiconductor light emitting device comprising:
a display device comprising a plurality of display modules;
an upper sealing layer disposed on the plurality of display modules;
a lower sealing layer disposed under the plurality of display modules, and
an injection device for injecting a resin material into a space formed by the upper sealing layer and the lower sealing layer.

8. The manufacturing device for display device of a semiconductor light emitting device according to claim 7, wherein the injection device for injecting the resin material comprises a plurality of injection devices, and
wherein at least of one of the plurality of injection devices comprise a device for injection and pressurization for the resin material.

9. The manufacturing device for display device of a semiconductor light emitting device according to claim 7, wherein at least of the plurality of injection devices comprise a suction device for suctioning a resin material.

10. The display device of a semiconductor light emitting device according to claim 4, wherein one end of the inclined resin layer is in contact with the first flattening layer, and the other end of the inclined resin layer is in contact with the second flattening layer.

11. The display device of a semiconductor light emitting device according to claim 10, wherein the first flattening layer is positioned higher than the second flattening layer.

12. The display device of a semiconductor light emitting device according to claim 1, wherein a lower surface of the above resin layer is flat.

13. The display device of a semiconductor light emitting device according to claim 1, further comprising an upper sealing layer is disposed on the substrate of the first display module and the substrate of the second display module, and
wherein the upper sealing layer is formed as an integral body.

14. The display device of a semiconductor light emitting device according to claim 13, wherein the upper surface of the resin layer is in contact with the lower surface of the upper sealing layer.

15. The display device of a semiconductor light emitting device according to claim 14, wherein the lower surface of the resin layer is in contact with the upper surface of the lower sealing layer.

16. The display device of a semiconductor light emitting device according to claim 1, further comprising a wiring protection layer disposed on each of the first side wiring and the second side wiring, and
wherein the resin layer is in contact with the wiring protection layer.

17. The display device of a semiconductor light emitting device according to claim 16, wherein a lower surface of the wiring protection layer is in contact with the lower sealing layer.

18. The display device of a semiconductor light emitting device according to claim 1, further comprising a module frame disposed under the substrate of the first and second display modules, and
wherein the module frame vertically overlaps the resin layer.

19. The display device of a semiconductor light emitting device according to claim 18, wherein the lower sealing layer is disposed spaced apart from the module frame.
